(19) United States
(12) Patent Application Publication
(10) Pub. No.: US 2015/0076607 A1
(43) Pub. Date: Mar. 19, 2015

(54) FIN FIELD EFFECT TRANSISTOR WITH MERGED METAL SEMICONDUCTOR ALLOY REGIONS

(71) Applicant: International Business Machines Corporation, Armonk, NY (US)

(72) Inventors: Emre Alptekin, Wappingers Falls, NY (US); Aysa M. Ozbek, Fishkill, NY (US); Ahmet S. Ozcan, Pleasantville, NY (US); Yiyi Wang, Chappaqua, NY (US)

(73) Assignee: International Business Machines Corporation, Armonk, NY (US)

(21) Appl. No.: 14/029,830

(22) Filed: Sep. 18, 2013

(51) Int. Cl. H01L 29/78; H01L 29/66

(52) U.S. Cl. CPC H01L 29/785; H01L 29/66795
USPC 257/365; 438/283

(57) ABSTRACT

Raised active regions having faceted semiconductor surfaces are formed on semiconductor fins by selective epitaxy such that the raised active regions are not merged among one another, but are proximal to one another by a distance less than a thickness of a metal semiconductor alloy region to be subsequently formed. A contiguous metal semiconductor alloy region is formed by depositing and reacting a metallic material with the semiconductor material of raised active regions. The contiguous metal semiconductor alloy region is in contact with angled surfaces of the plurality of raised active regions, and can provide a greater contact area and lower parasitic contact resistance than a semiconductor structure including merged semiconductor fins of comparable sizes. Merged fins enable smaller, and/or fewer, contact via structures than a total number of raised active regions can be employed to reduce parasitic capacitance between a gate electrode and the contact via structures.

### BACKGROUND

The present disclosure relates to a semiconductor structure, and particularly to fin field effect transistors including merged metal semiconductor alloy portions, and a method of manufacturing the same.

State-of-the art complementary metal oxide semiconductor (CMOS) devices employ fin field effect transistors. One of the key design choices is whether raised active regions formed by selective epitaxy are to be merged with one another or to remain unmerged. Each choice offers advantages and disadvantages. On one hand, fin field effect transistors including unmerged raised active regions benefit from lower contact resistance and improved direct current (DC) performance due to increased silicide contact areas corresponding to wrapping around of the silicides around the faceted surfaces of the unmerged raised active regions. On the other hand, fin field effect transistors including merged raised active regions benefit from reduced parasitic capacitance between a gate electrode and contact via structures due to the reduction in the number of contact via structures. Thus, a method and a structure are desired for simultaneously reducing the contact resistance between raised active regions and contact via structures and the parasitic capacitance between a gate electrode and the contact via structures.

### SUMMARY

Raised active regions having faceted semiconductor surfaces are formed on semiconductor fins by selective epitaxy such that the raised active regions are not merged among one another, but are proximal to one another by a distance less than a thickness of a metal semiconductor alloy region to be subsequently formed. A metallic material is deposited on the faceted semiconductor surfaces and a contiguous metal semiconductor alloy region is formed by reacting the deposited metallic material with the semiconductor material of raised active regions. The contiguous metal semiconductor alloy region is in contact with angled surfaces of the plurality of raised active regions, and can provide a greater contact area than a semiconductor structure including merged semiconductor fins of comparable sizes. A narrower contact via structure or a lesser number of contact via structures than a total number of raised active regions can be employed to reduce parasitic capacitance between a gate electrode and the contact via structures.

According to an aspect of the present disclosure, a semiconductor structure includes a plurality of semiconductor fins located on a substrate, and a plurality of raised active regions. Each of the plurality of raised active regions is located on sidewalls of a corresponding semiconductor fin among the plurality of semiconductor fins, and is laterally spaced from any other of the plurality of raised active regions. The semiconductor structure further includes a contiguous metal semiconductor alloy region contacting surfaces of at least two of the raised active regions.

According to another aspect of the present disclosure, a method of forming a semiconductor structure is provided. A plurality of semiconductor fins is formed on a substrate. A plurality of raised active regions is formed on the plurality of semiconductor fins. Each of the plurality of raised active regions is laterally spaced from any other of the plurality of raised active regions. A contiguous metal semiconductor alloy region is formed directly on at least two of the raised active regions.

### BRIEF DESCRIPTION OF SEVERAL VIEWS OF THE DRAWINGS

FIG. 1A is a top-down view of a first exemplary semiconductor structure after formation of a plurality of fin-defining mask structures over a substrate including a vertical stack, from bottom to top, of a handle substrate, an insulator layer, and a top semiconductor layer according to a first embodiment of the present disclosure.

FIG. 1B is a vertical cross-sectional view of the first exemplary semiconductor structure along the vertical plane B-B′ of FIG. 1A.

FIG. 1C is a vertical cross-sectional view of the first exemplary semiconductor structure along the vertical plane C-C′ of FIG. 1A.

FIG. 2A is a top-down view of the first exemplary semiconductor structure after formation of semiconductor fins having substantially vertical sidewalls employing an anisotropic etch according to the first embodiment of the present disclosure.

FIG. 2B is a vertical cross-sectional view of the first exemplary semiconductor structure along the vertical plane B-B′ of FIG. 2A.

FIG. 2C is a vertical cross-sectional view of the first exemplary semiconductor structure along the vertical plane C-C′ of FIG. 2A.

FIG. 3A is a top-down view of the first exemplary semiconductor structure after removal of the plurality of fin-defining mask structures according to the first embodiment of the present disclosure.

FIG. 3B is a vertical cross-sectional view of the first exemplary semiconductor structure along the vertical plane B-B′ of FIG. 3A.

FIG. 3C is a vertical cross-sectional view of the first exemplary semiconductor structure along the vertical plane C-C′ of FIG. 3A.

FIG. 4A is a top-down view of the first exemplary semiconductor structure after formation of a gate stack and a gate spacer according to the first embodiment of the present disclosure.

FIG. 4B is a vertical cross-sectional view of the first exemplary semiconductor structure along the vertical plane B-B′ of FIG. 4A.

FIG. 4C is a vertical cross-sectional view of the first exemplary semiconductor structure along the vertical plane C-C′ of FIG. 4A.

FIG. 4D is a vertical cross-sectional view of the first exemplary semiconductor structure along the vertical plane D-D′ of FIG. 4A.

FIG. 5A is a top-down view of the first exemplary semiconductor structure after formation of raised active regions by selective epitaxy according to the first embodiment of the present disclosure.

FIG. 5B is a vertical cross-sectional view of the first exemplary semiconductor structure along the vertical plane B-B′ of FIG. 5A.

FIG. 5C is a vertical cross-sectional view of the first exemplary semiconductor structure along the vertical plane C-C′ of FIG. 5A.

FIG. 5D is a vertical cross-sectional view of the first exemplary semiconductor structure along the vertical plane D-D′ of FIG. 5A.

FIG. 6A is a top-down view of the first exemplary semiconductor structure after formation of merged metal semiconductor alloy regions according to the first embodiment of the present disclosure.

FIG. 6B is a vertical cross-sectional view of the first exemplary semiconductor structure along the vertical plane B-B′ of FIG. 6A.

FIG. 6C is a vertical cross-sectional view of the first exemplary semiconductor structure along the vertical plane C-C′ of FIG. 6A.

FIG. 6D is a vertical cross-sectional view of the first exemplary semiconductor structure along the vertical plane D-D′ of FIG. 6A.

FIG. 7A is a top-down view of the first exemplary semiconductor structure after formation of a contact level dielectric material layer and contact via structures according to the first embodiment of the present disclosure.

FIG. 7B is a vertical cross-sectional view of the first exemplary semiconductor structure along the vertical plane B-B′ of FIG. 7A.

FIG. 7C is a vertical cross-sectional view of the first exemplary semiconductor structure along the vertical plane C-C′ of FIG. 7A.

FIG. 7D is a vertical cross-sectional view of the first exemplary semiconductor structure along the vertical plane D-D′ of FIG. 7A.

FIG. 8A is a top-down view of a first variation of the first exemplary semiconductor structure according to the first embodiment of the present disclosure.

FIG. 8B is a vertical cross-sectional view of the first variation of the first exemplary semiconductor structure along the vertical plane B-B′ of FIG. 8A.

FIG. 8C is a vertical cross-sectional view of the first variation of the first exemplary semiconductor structure along the vertical plane C-C′ of FIG. 8A.

FIG. 8D is a vertical cross-sectional view of the first variation of the first exemplary semiconductor structure along the vertical plane D-D′ of FIG. 8A.

FIG. 9A is a top-down view of a second variation of the first exemplary semiconductor structure according to the first embodiment of the present disclosure.

FIG. 9B is a vertical cross-sectional view of the second variation of the first exemplary semiconductor structure along the vertical plane B-B′ of FIG. 9A.

FIG. 9C is a vertical cross-sectional view of the second variation of the first exemplary semiconductor structure along the vertical plane C-C′ of FIG. 9A.

FIG. 9D is a vertical cross-sectional view of the second variation of the first exemplary semiconductor structure along the vertical plane D-D′ of FIG. 9A.

FIG. 10A is a top-down view of a third variation of the first exemplary semiconductor structure according to the first embodiment of the present disclosure.

FIG. 10B is a vertical cross-sectional view of the third variation of the first exemplary semiconductor structure along the vertical plane B-B′ of FIG. 10A.

FIG. 10C is a vertical cross-sectional view of the third variation of the first exemplary semiconductor structure along the vertical plane C-C′ of FIG. 10A.

FIG. 10D is a vertical cross-sectional view of the third variation of the first exemplary semiconductor structure along the vertical plane D-D′ of FIG. 10A.

FIG. 11A is a top-down view of a second exemplary semiconductor structure after formation of semiconductor fins having substantially vertical sidewalls employing an anisotropic etch according to a second embodiment of the present disclosure.

FIG. 11B is a vertical cross-sectional view of the second exemplary semiconductor structure along the vertical plane B-B′ of FIG. 11A.

FIG. 11C is a vertical cross-sectional view of the second exemplary semiconductor structure along the vertical plane C-C′ of FIG. 11A.

FIG. 12A is a top-down view of the second exemplary semiconductor structure after formation of a shallow trench isolation structure according to the second embodiment of the present disclosure.

FIG. 12B is a vertical cross-sectional view of the second exemplary semiconductor structure along the vertical plane B-B′ of FIG. 12A.

FIG. 12C is a vertical cross-sectional view of the second exemplary semiconductor structure along the vertical plane C-C′ of FIG. 12A.

FIG. 13A is a top-down view of the second exemplary semiconductor structure after formation of a contact level dielectric material layer and contact via structures according to the second embodiment of the present disclosure.

FIG. 13B is a vertical cross-sectional view of the second exemplary semiconductor structure along the vertical plane B-B′ of FIG. 13A.

FIG. 13C is a vertical cross-sectional view of the second exemplary semiconductor structure along the vertical plane C-C′ of FIG. 13A.

FIG. 13D is a vertical cross-sectional view of the second exemplary semiconductor structure along the vertical plane D-D′ of FIG. 13A.

### DETAILED DESCRIPTION

As stated above, the present disclosure relates to fin field effect transistors including merged metal semiconductor alloy portions and a method of manufacturing the same. Aspects of the present disclosure are now described in detail with accompanying figures. It is noted that like reference numerals refer to like elements across different embodiments. The drawings are not necessarily drawn to scale.

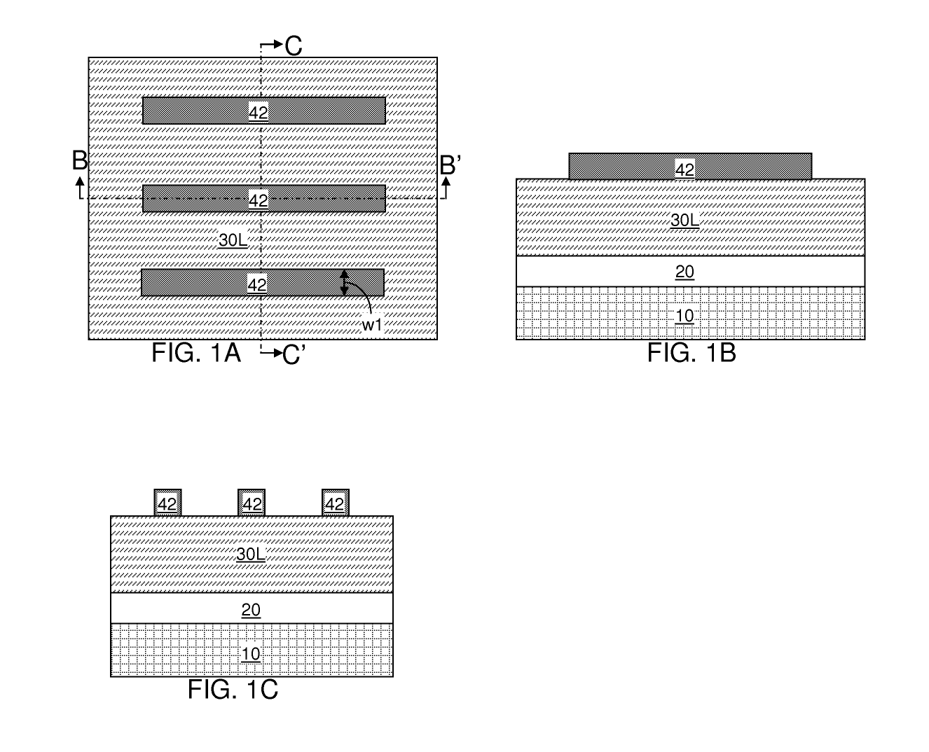

Referring to FIGS. 1A-1C, a first exemplary semiconductor structure according to a first embodiment of the present disclosure includes a vertical stack of a handle substrate 10, and an insulator layer 20, and a semiconductor layer 30L.

The handle substrate 10 can include a semiconductor material, an insulator material, or a conductive material. The handle substrate 10 provides mechanical support to the insulator layer 20 and the semiconductor layer 30L. The handle substrate 10 can be single crystalline, polycrystalline, or amorphous. The thickness of the handle substrate 10 can be from 50 microns to 2 mm, although lesser and greater thicknesses can also be employed.

The insulator layer 20 includes a dielectric material. Non-limiting examples of the insulator layer 20 include silicon oxide, silicon nitride, sapphire, and combinations or stacks thereof. The thickness of the insulator layer 20 can be, for example, from 100 nm to 100 microns, although lesser and greater thicknesses can also be employed. The handle substrate 10 and the insulator layer 20 collectively function as a substrate on which the semiconductor layer 30L is located.

The semiconductor layer 30L includes a semiconductor material. The semiconductor material of the semiconductor layer 30L can be an elemental semiconductor material, an alloy of at least two elemental semiconductor materials, a compound semiconductor material, or a combination thereof. The semiconductor layer 30L can be intrinsic or doped with electrical dopants of p-type or n-type. The semiconductor material of the semiconductor layer 30L can be single crystalline or polycrystalline. In one embodiment, the semiconductor layer 30L can be a single crystalline semiconductor layer. In one embodiment, the semiconductor material of the semiconductor layer 30L can be single crystalline silicon. The thickness of the semiconductor layer 30L can be, for example, from 10 nm to 300 nm, although lesser and greater thicknesses can also be employed.

A plurality of fin-defining mask structures 42 is formed over the semiconductor layer 30L. The plurality of fin-defining mask structures 42 is a set of mask structures that cover the regions of the semiconductor layer 30L that are subsequently converted into semiconductor fins. Thus, the plurality of fin-defining mask structures 42 is subsequently employed to define the area of the semiconductor fins. The plurality of fin-defining mask structures 42 can include a dielectric material such as silicon nitride, silicon oxide, and silicon oxynitride. In one embodiment, the plurality of fin-defining mask structures 42 can includes a material selected from an undoped silicate glass (USG), a fluorosilicate glass (FSG), a phosphosilicate glass (PSG), a borosilicate glass (BSG), and a borophosphosilicate glass (BPSG).

The plurality of fin-defining mask structures 42 can be formed, for example, by depositing a planar dielectric material layer and lithographically patterning the dielectric material layer. The planar dielectric material layer can be deposited, for example, by physical vapor deposition (PVD), chemical vapor deposition (CVD), and/or other suitable methods for depositing a dielectric material. The thickness of the planar dielectric material layer can be from 5 nm to 100 nm, although lesser and greater thicknesses can also be employed.

The planar dielectric material layer can be subsequently patterned to form the plurality of fin-defining mask structures 42. In one embodiment, each fin-defining mask structure 42 can laterally extend along a lengthwise direction. Further, each fin-defining mask structure 42 can have a pair of sidewalls that are separated along a widthwise direction, which is perpendicular to the lengthwise direction. In one embodiment, each fin-defining mask structure 42 can have a rectangular horizontal cross-sectional area. In one embodiment, each fin-defining mask structures 42 can have the same width w1.

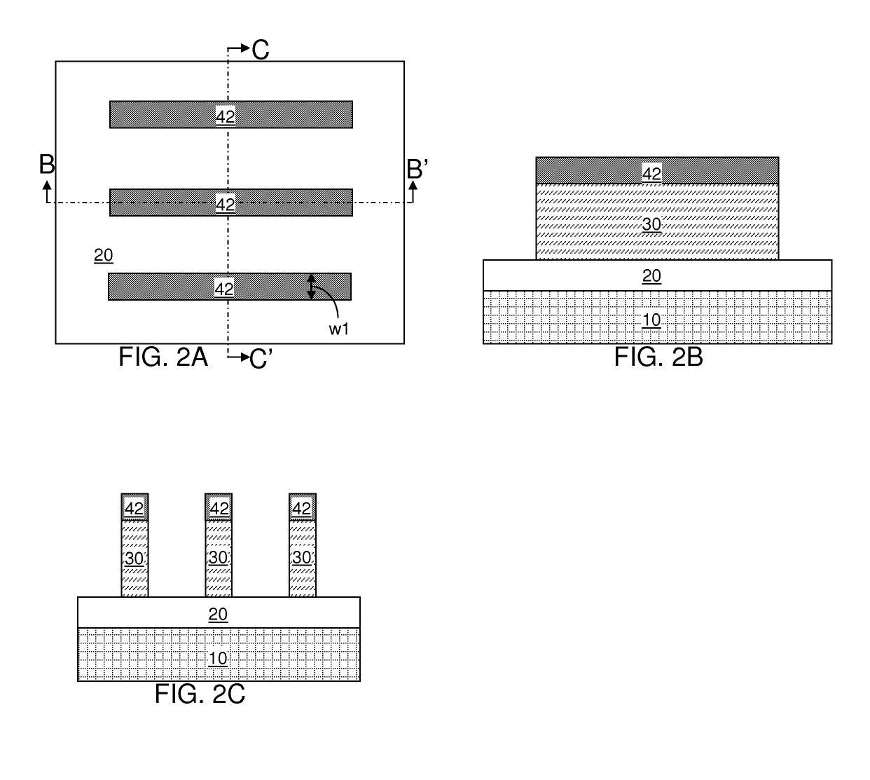

Referring to FIGS. 2A-2C, the semiconductor layer 30L is patterned to form a plurality of semiconductor fins 30. The formation of the plurality of semiconductor fins 30 can be performed employing an anisotropic etch process, which can be a reactive ion etch. The plurality of semiconductor fins 30 has substantially same horizontal cross-sectional shapes as the fin-defining mask structures 42. As used herein, two shapes are “substantially same” if the differences between the two shapes is due to atomic level roughness and does not exceed 2 nm. The semiconductor layer 30L is etched employing the anisotropic etch process in which the plurality of fin-defining mask structures 42 is employed as an etch mask. The plurality of semiconductor fins 30 is formed on the insulator layer 20. In one embodiment, the plurality of semiconductor fins 30 can include a single crystalline semiconductor material, and can have the same width w1.

The sidewalls of each semiconductor fin 30 can be vertically coincident with sidewalls of an overlying fin-defining mask structure 42. As used herein, a first surface and a second surface are vertically coincident if the first surface and the second surface are within a same vertical plane. In one embodiment, the height of the plurality of semiconductor fins 30 can be greater than the width w1 of each semiconductor fin 30.

The plurality of semiconductor fins 30 has substantially vertical sidewalls. As used herein, a surface is “substantially vertical” if the difference between the surface and a vertical surface is due to atomic level roughness and does not exceed 2 nm. Each of the plurality of semiconductor fins 30 can be a single crystalline semiconductor fin that laterally extends along a lengthwise direction. As used herein, a “lengthwise direction” is a horizontal direction along which an object extends the most. A “widthwise direction” is a horizontal direction that is perpendicular to the lengthwise direction.

In one embodiment, each of the plurality of semiconductor fins 30 extends along the lengthwise direction with a substantially rectangular vertical cross-sectional shape. As used herein, a “substantially rectangular shape” is a shape that differs from a rectangular shape only due to atomic level roughness that does not exceed 2 nm. The substantially rectangular vertical cross-sectional shape is a shape within a plane including a vertical direction and a widthwise direction. The handle substrate 10 and the insulator layer 20 collectively functions as a substrate on which the plurality of semiconductor fins 30 is located. The substantially rectangular vertical cross-sectional shape adjoins a horizontal interface with a top surface of the combination of the insulator layer 20 and the handle substrate 10, i.e., the substrate (10, 20).

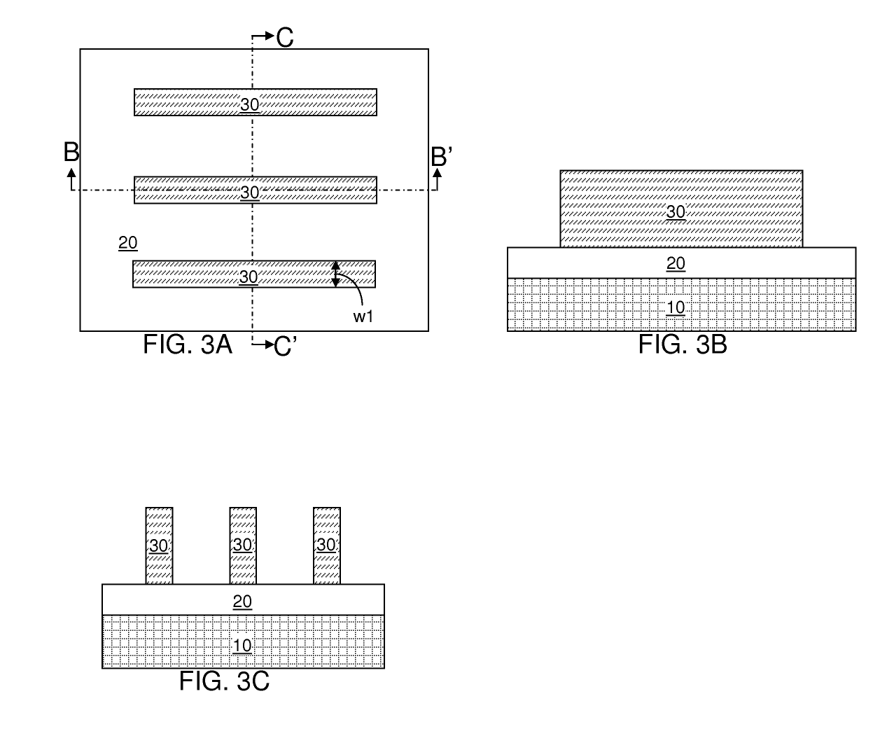

Referring to FIGS. 3A-3C, the plurality of fin-defining mask structures 42 can be removed selective to the plurality of semiconductor fins 30 by an etch process. The etch can be an isotropic etch or an anisotropic etch. The etch process can be selective, or non-selective, to the dielectric material of the insulator layer 20. In one embodiment, the plurality of fin-defining mask structures 42 can be removed selective to the plurality of semiconductor fins 30 and the insulator layer 20 employing a wet etch chemistry.

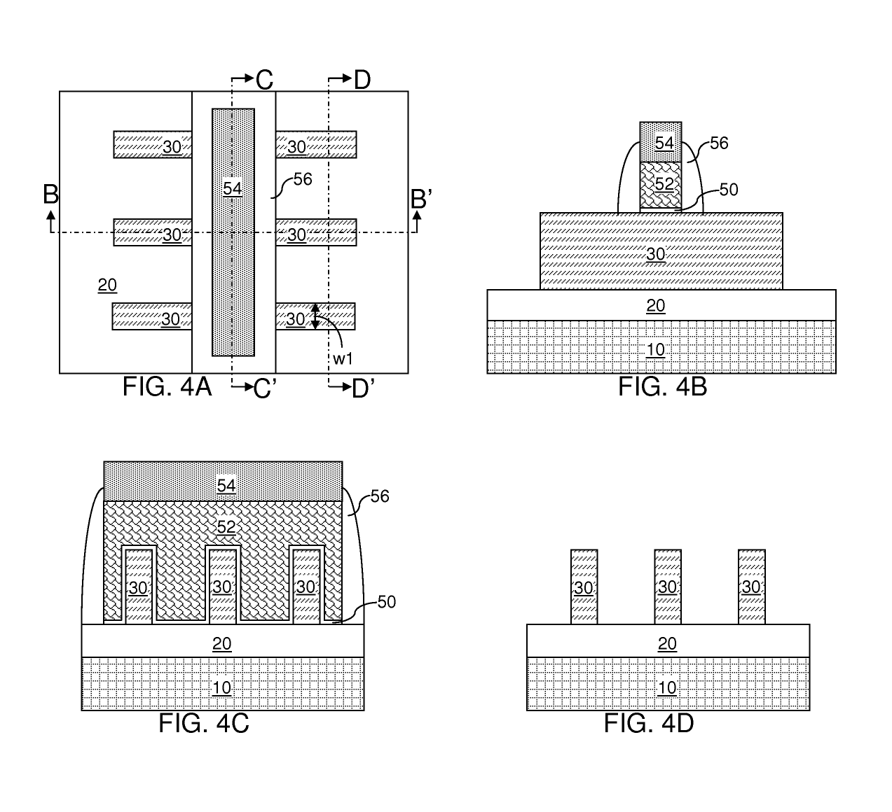

Referring to FIGS. 4A-4D, a gate stack including a gate dielectric 50, a gate electrode 52, and an optional gate cap dielectric 54 can be formed across the plurality of semiconductor fins 30 such that the gate stack (50, 52, 54) straddles each of the plurality of semiconductor fins 30. The gate dielectric 50 can include a silicon-oxide-based dielectric material such as silicon oxide or silicon oxynitride, or silicon nitride, and/or a dielectric metal oxide having a dielectric constant greater than 8.0 and is known as a high dielectric constant (high-k) dielectric material in the art. The thickness of the gate dielectric 50 can be in a range from 1 nm to 10 nm, although lesser and greater thicknesses can also be employed. The gate dielectric 50 is in contact with a top surface and sidewall surfaces of each semiconductor fin 30. The gate electrode 52 can include a conductive material such as a doped semiconductor material, a metallic material, and/or a combination thereof. The gate electrode 52 is in contact with the gate dielectric 50. The gate cap dielectric 54 includes a dielectric material such as silicon oxide, silicon nitride, silicon oxynitride, or a combination thereof.

The formation of the gate dielectric 50, the gate electrode 52, and the optional gate cap dielectric 54 can be effected, for example, by deposition of a stack of a gate dielectric layer, a gate electrode layer, and a gate cap dielectric layer, and by subsequent patterning of the gate cap dielectric layer, the gate electrode layer, and the gate dielectric layer. The patterning of the gate cap dielectric layer and the gate electrode layer can be performed employing a combination of lithographic methods and at least one anisotropic etch. The patterning of the gate dielectric layer can be performed by an isotropic etch that is selective to the semiconductor material of the plurality of semiconductor fins 30.

A gate spacer 56 can be formed around the gate stack (50, 52, 54). The gate spacer 56 can be formed, for example, by depositing a conformal dielectric material layer on the plurality of semiconductor fins 30 and the gate stack (50, 52, 54), and anisotropically etching the conformal dielectric layer. The anisotropic etch includes an overetch component that removes vertical portions of the conformal dielectric material layer from the sidewalls of the plurality of semiconductor fins 30. An upper portion of the gate cap dielectric 54 can be vertically recessed during the overetch of the conformal dielectric material layer. The remaining portions of the conformal dielectric material layer constitute the gate spacer 56, which laterally surrounds the gate stack (50, 52, 54).

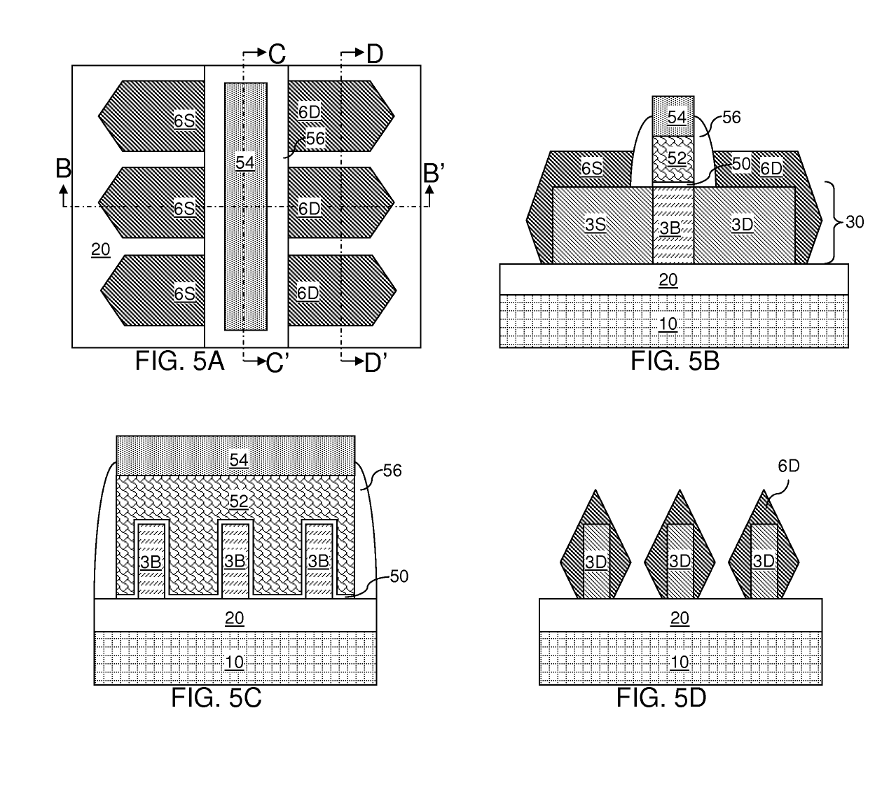

Referring to FIGS. 5A-5D, a plurality of raised active regions (6S, 6D) are formed on the plurality of semiconductor fins 30. As used herein, a raised active region refers to a doped semiconductor material portion that protrudes above a topmost surface of an active region of a semiconductor device. As used herein, an active region refers to a semiconductor material portion within a semiconductor device through which charge carriers flow during operation of the semiconductor device. The plurality of raised active regions include raised source regions 6S that are formed on a source side of the semiconductor fins 30 with respect to the gate stack (50, 52, 54) and raised drain regions 6D that are formed on a drain side of the semiconductor fins 30 with respect to the gate stack (50, 52, 54).

The plurality of raised active regions (6S, 6D) can be formed, for example, by selective deposition of a semiconductor material. The plurality of raised active regions (6S, 6D) can be doped with electrical dopants, which can be p-type dopants or n-type dopants. If the plurality of semiconductor fins 30 is doped with dopants of a first conductivity type prior to formation of the gate stack (50, 52, 54), the plurality of raised active regions (6S, 6D) can be doped with dopants of a second conductivity type, which is the opposite of the first conductivity type. If the first conductivity type is p-type, the second conductivity type is n-type, and vice versa.

The doping of the plurality of raised active regions (6S, 6D) can be performed by in-situ doping, i.e., during deposition of the plurality of raised active regions (6S, 6D), or by ex-situ doping, i.e., after deposition of the plurality of raised active regions (6S, 6D). Exemplary methods for performing the ex-situ doping include, but are not limited to, ion implantation, plasma doping, and outdiffusion of dopants from a disposable dopant-including material that is temporarily deposited and subsequently removed.

A portion of each semiconductor fin 30 that underlies a raised source region 6S can be converted into a source region 3S, and a portion of each semiconductor fin 30 that underlies the raised drain region 6D can be converted into a drain region 3D. The source regions 3S and the drain regions 3D have the same type of doping as the plurality of raised active regions (6S, 6D). The doping of the source regions 3S and the drain regions 3D can be performed by ion implantation prior to, or after, formation of the plurality of raised active regions (6S, 6D), and/or by outdiffusion of dopants from the plurality of raised active regions (6S, 6D).

The portion of each semiconductor fin 30 that is not converted into a source region 3S or a drain region 3D constitutes a channel region 3B. The channel regions 3B collectively function as a channel of a field effect transistor. The source regions 3S and the raised source regions 6S collectively function as a source of the field effect transistor. The drain regions 3D and the raised drain regions 6D collectively function as a drain of the field effect transistor.

Each raised source region 6S is in contact with an underlying source regions 3S, and is located outside the semiconductor fin (3B, 3S, 3D) including the underlying source region 3S. Each raised drain region 6D is in contact with an underlying drain regions 3D, and is located outside the semiconductor fin (3B, 3S, 3D) including the underlying drain region 3D. A pair of vertical planes that include a pair of sidewalls of each channel region 3B includes vertical interfaces between a source region 3S and a raised source region 6S, and vertical interfaces between a drain region 3D and a raised drain region 6D. The horizontal plane including the top surfaces of the channel regions 3B includes the horizontal interfaces between the source regions 3S and the raised source regions 6S, and the horizontal interfaces between the drain regions 3D and the raised drain regions 6D.

The plurality of raised active regions (6S, 6D) is formed on outer sidewalls of the gate spacer 56. In one embodiment, the plurality of semiconductor fins 30 can be a plurality of single crystalline semiconductor fins, and the plurality of raised active regions (6S, 6D) can be formed by selective epitaxy of a semiconductor material. In this case, each of the plurality of raised active regions (6S, 6D) can be epitaxially aligned to the corresponding semiconductor fin among the plurality of semiconductor fins (3S, 3D, 3B), i.e., the underlying semiconductor fin on which each raised active region (6S, 6D) epitaxially grows. In other words, the plurality of raised active regions (6S, 6D) can be formed by a selective epitaxy process such that each of the plurality of raised active regions (6S, 6D) is in epitaxial alignment with an underlying single crystalline semiconductor fin.

The duration of the selective epitaxy process can be controlled such that each of the plurality of raised active regions (6S, 6D) is laterally spaced from any other of the plurality of raised active regions (6S, 6D), i.e., does not merge with any other raised active region (6S, 6D). In one embodiment, the plurality of raised active regions (6S, 6D) can be formed with crystallographic facets. In one embodiment, the angles between the crystallographic facets of the raised active regions (6S, 6D) and a vertical line (i.e., a line that is perpendicular to the top surface of the insulator layer 20) can be greater than 0 degrees and less than 90 degrees for all facets formed on sidewalls of the plurality of semiconductor fins (3S, 3D, 3B). The total number of the raised active regions 6S can be the same as the total number of the source regions 3S, and the total number of the raised drain regions 6D can be the same as the total number of the drain regions 6D. Because the raised source regions 6S are not merged among one another, a physical gap exists between each neighboring pair of raised source regions 6S. Likewise, because the raised drain regions 6D are not merged among one another, a physical gap exists between each neighboring pair of raised drain regions 6D.

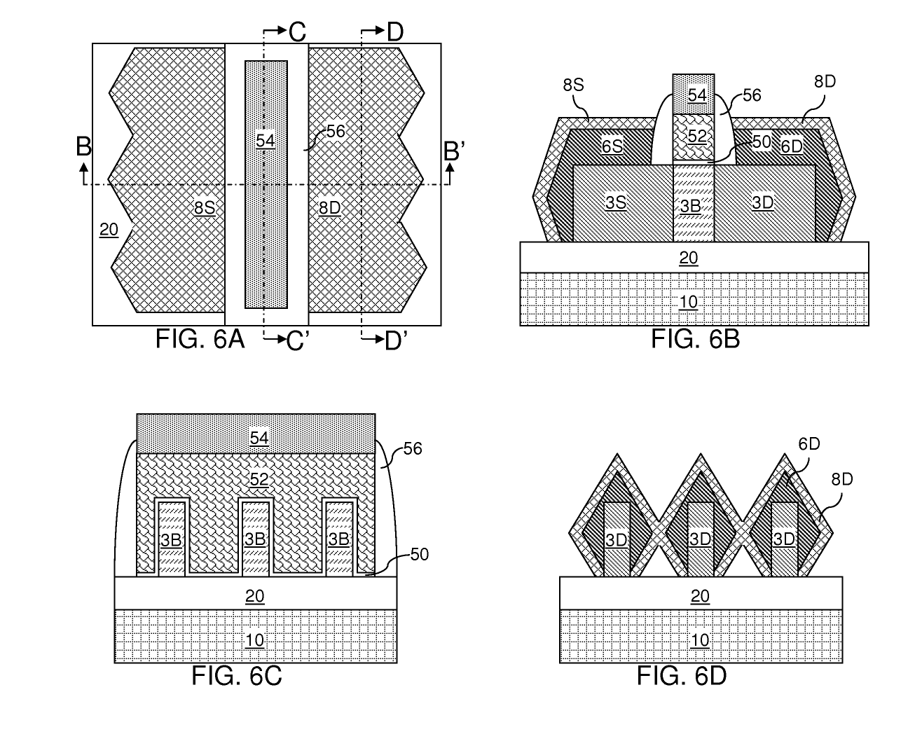

Referring to FIGS. 6A-6D, contiguous metal semiconductor alloy regions (8S, 8D) are formed on the plurality of raised active regions (6S, 6D). As used herein, an element is “contiguous” if there exists a path contained entirely within the element for any pair of points within the element. The contiguous metal semiconductor alloy regions (8S, 8D) include a source-side contiguous metal semiconductor alloy region 8S that is formed directly on a plurality of raised source regions 6S, and a drain-side contiguous metal semiconductor alloy region 8D that is formed directly on a plurality of raised drain regions 6D. Thus, each contiguous metal semiconductor alloy region (8S, 8D) can be formed directly on at least two of the raised active regions (6S, 6D).

In one embodiment, the contiguous metal semiconductor alloy regions (8S, 8D) can be formed by depositing a metallic material on surfaces of the plurality of raised active regions (6S, 6D), and by reacting the deposited metallic material with the semiconductor material within the plurality of raised active regions (6S, 6D). The metallic material can be deposited by chemical vapor deposition, physical vapor deposition, or vacuum evaporation. The deposited metallic material can be, for example, W, Ti, Ta, Ni, Pt, or any other material known to form a metal semiconductor alloy upon reaction with the semiconductor material of the plurality of raised active regions (6S, 6D). For example, if the plurality of raised active regions (6S, 6D) includes silicon, the deposited metallic material can be a material known to form a metal silicide upon reaction with silicon.

In another embodiment, the contiguous metal semiconductor alloy regions (8S, 8D) can be formed by deposition of a metal semiconductor alloy material, for example, by chemical vapor deposition or physical vapor deposition. The metal semiconductor alloy material can be, for example, a metal silicide such as tungsten silicide, titanium silicide, tantalum silicide, nickel silicide, a nickel-platinum silicide, or a combination thereof. In one embodiment, the metal semiconductor alloy material can be titanium silicide deposited by chemical vapor deposition directly on surfaces of the plurality of raised active regions (6S, 6D) selective to surfaces of dielectric material regions such as the insulator layer 20, the optional gate cap dielectric 54, and the gate spacer 56.

The thickness of the deposited metallic material or the deposited metal semiconductor alloy material can be selected such that the metal semiconductor alloy material formed on the raised source regions 6S merge to form a source-side contiguous metal semiconductor alloy region 8S as a single contiguous structure, and the metal semiconductor alloy material formed on the raised drain regions 6D merge to form a drain-side contiguous metal semiconductor alloy region 8D as another single contiguous structure.

If a metallic material is deposited on the raised active regions (6S, 6D), the volume of the contiguous metal semiconductor alloy regions (8S, 8D) can be estimated employing a known volume expansion factor for formation of a metal semiconductor alloy from a combination of a semiconductor material and a metal with respect to the volume of a reacted portion of the semiconductor material. For example, a typical metal silicide formation process induces a volume expansion of about 25% with respect to the volume of silicon consumed during the silicidation process. Thus, by controlling the amount of deposited metallic material and the duration of an anneal that forms the metal silicide alloy, the metal semiconductor alloy material formed on multiple raised active regions (6S, 6D) during a metallization anneal process can merge to constitute the contiguous metal semiconductor alloy regions (8S, 8D), which are contiguous structures.

If a metal semiconductor alloy material is deposited, the thickness of the deposited metal semiconductor alloy material can be controlled such that multiple metal semiconductor alloy portions deposited on multiple raised active regions (6S, 6D) can to constitute the contiguous metal semiconductor alloy regions (8S, 8D), which are contiguous structures.

The first exemplary semiconductor structure includes a plurality of semiconductor fins (3S, 3D, 3B) located on a substrate (10, 20), a plurality of raised active regions (6S or 6D), and a contiguous metal semiconductor alloy region (8S or 8D). Each of the plurality of raised active regions (6S or 6D) is located on sidewalls of a corresponding semiconductor fin among the plurality of semiconductor fins (3S, 3D, 3B), and is laterally spaced from any other of the plurality of raised active regions (6S or 6D). The contiguous metal semiconductor alloy region (8S or 8D) contacts surfaces of at least two of the raised active regions (6S or 6D).

An interface between the plurality of raised active regions (6S, 6D) and the contiguous metal semiconductor alloy region (8S, 8D) can be at an angle that is greater than 0 degree and less than 90 degree with respect to a vertical direction, which is perpendicular to the top surface of the insulator layer 20 and is included within the sidewalls of the plurality of semiconductor fins (3S, 3D, 3B). In one embodiment, the plurality of raised active regions (6S or 6D) can include silicon, and the contiguous metal semiconductor alloy region (8S or 8D) can include a metal silicide.

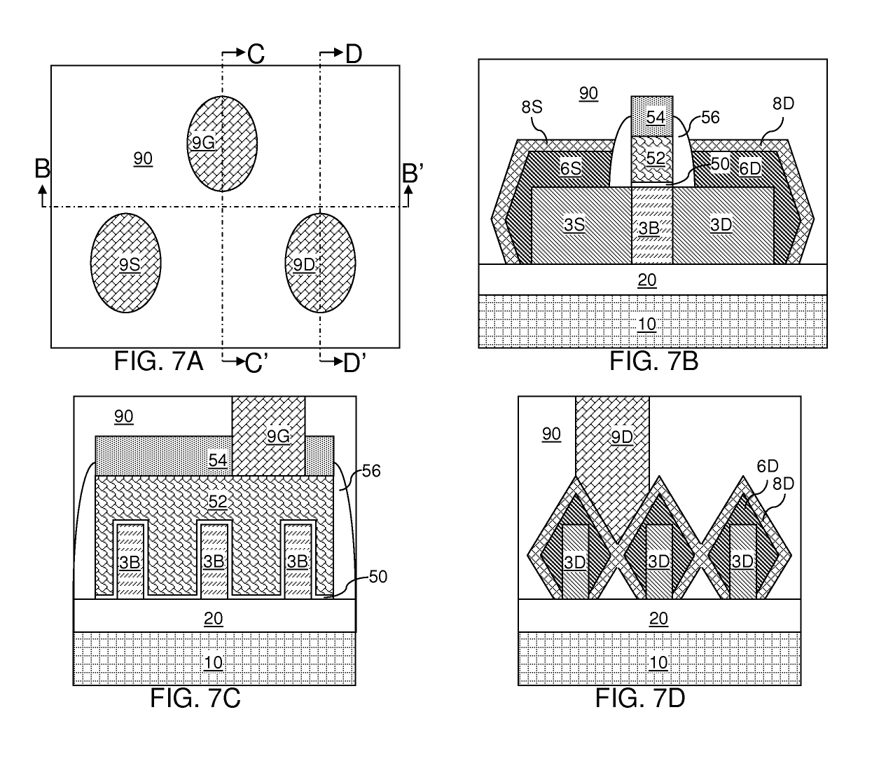

Referring to FIGS. 7A-7D, a contact level dielectric material layer 90 and various contact via structures (9S, 9D, 9G). The contact level dielectric material layer 90 includes a dielectric material such as silicon oxide, silicon nitride, and/or porous or non-porous organosilicate glass (OGS). The contact level dielectric material layer 90 can be formed, for example, by chemical vapor deposition or spin coating. Optionally, the top surface of the contact level dielectric material layer 90 can be planarized, for example, by chemical mechanical planarization.

The various contact via structures (9S, 9D, 9G) can include a source-side contact via structure 9S that contacts the source-side contiguous metal semiconductor alloy region 8S, a drain-side contact via structure 9D that contacts the drain-side contiguous metal semiconductor alloy region 8D, and a gate-side contact via structure 9G that contacts the gate electrode 52. In one embodiment, a single instance of source-side contact via structure 9S can be employed to provide electrical contact to all source regions 3S and all raised source regions 6S because the source-side contiguous metal semiconductor alloy region 8S is in physical contact with all raised source regions 6S. Likewise, a single instance of drain-side contact via structure 9D can be employed to provide electrical contact to all drain regions 3D and all raised drain regions 6D because the drain-side contiguous metal semiconductor alloy region 8D is in physical contact with all raised drain regions 6D.

The contact level dielectric material layer 90 is in contact with the contiguous metal semiconductor alloy regions (8S, 8D). In one embodiment, the contact level dielectric material layer 90 can be deposited by a conformal deposition method, and fill all spaces between various portions of the contiguous metal semiconductor alloy regions (8S, 8D). The source-side contact via structure 9S and the drain-side contact via structure 9D extend through the contact level dielectric material layer, and in contact with the contiguous metal semiconductor alloy regions (8S, 8D).

A dielectric material portion, such as the insulator layer 20, can be located below the horizontal plane including bottommost surfaces of the plurality of raised active regions (6S, 6D). In one embodiment, the contiguous metal semiconductor alloy regions (8S, 8D) can be formed employing a conformal deposition method for deposition of a metallic material or a metal semiconductor alloy material. The conformal deposition method can be, for example, chemical vapor deposition. In this case, the dielectric material portion (e.g., of the insulator layer 20) can be is in contact with the bottommost surface of the contiguous metal semiconductor alloy regions (8S, 8D). In one embodiment, the plurality of raised active regions (6S, 6D) can be formed over a dielectric material portion such as the insulator layer 20, and the contiguous metal semiconductor alloy regions (8S, 8D) can be formed directly on a top surface of the dielectric material portion (e.g., of the insulator layer 20).

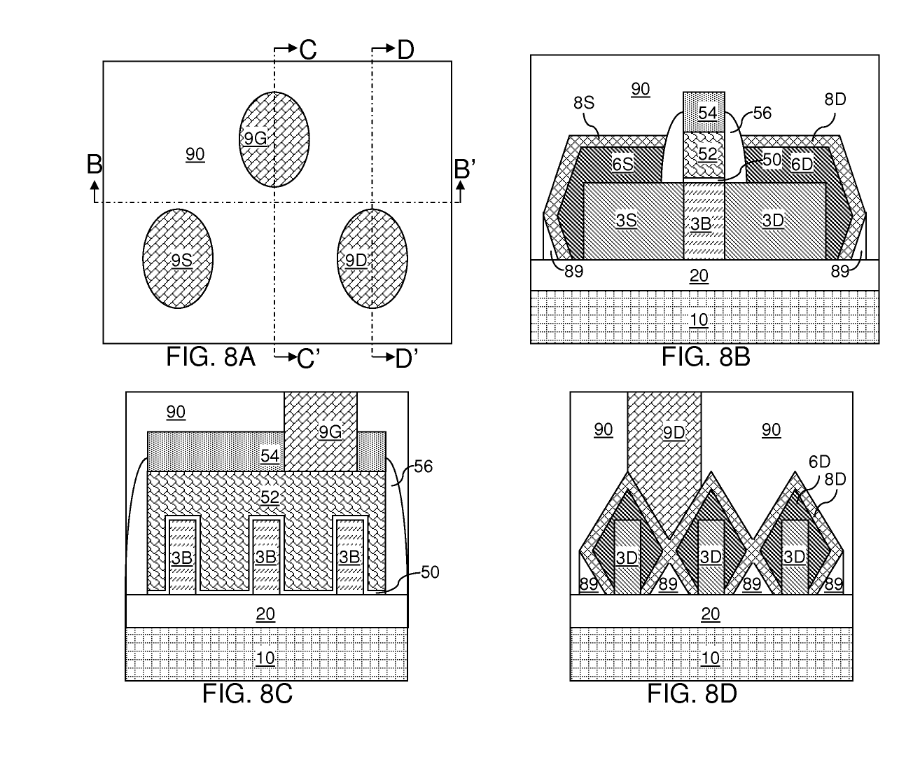

Referring to FIGS. 8A-8D, a first variation of the first exemplary semiconductor structure can be derived from the first exemplary semiconductor structure by forming the contact level dielectric material layer 90 employing a non-conformal deposition method. In this case, cavities 89 can be formed in volumes bounded by a portion of a top surface of the insulator layer 20 and at least one downward-facing outer surface of the contiguous metal semiconductor alloy regions (8S, 8D). As used herein, a surface is “downward facing” if the product between a unit vector pointing outward from the surface and a vertical unit vector (which is perpendicular to the top surface of the insulator layer 20 and points upward) is negative. At least one of the cavities 89 can be located underneath a contiguous metal semiconductor alloy region (8S or 8D) and between a neighboring pair of raised active regions among the plurality of raised active regions (6S, 6D). A dielectric material portion (such as the insulator layer 20) can be located below a horizontal plane including bottommost surfaces of the plurality of raised active regions (6S, 6D). In one embodiment, the contiguous metal semiconductor alloy regions (8S, 8D) can be formed employing a conformal deposition method for deposition of a metallic material or a metal semiconductor alloy material. In this case, the dielectric material portion can be in contact with a bottommost surface of the contiguous metal semiconductor alloy region.

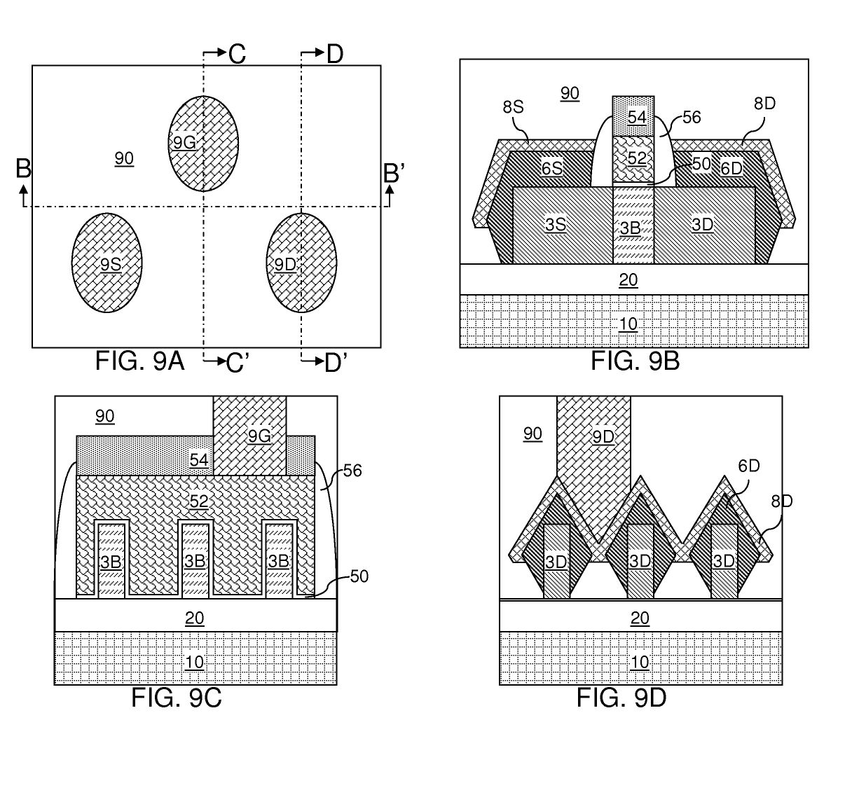

Referring to FIGS. 9A-9D, a second variation of the first exemplary semiconductor structure can be derived from the first exemplary semiconductor structure by forming the contiguous metal semiconductor alloy regions (8S, 8D) employing a non-conformal deposition method for deposition of a metallic material or a metal semiconductor alloy material. The non-conformal deposition method can be, for example, physical vapor deposition or vacuum evaporation. A dielectric material portion (such as the insulator layer 20) can be located below a horizontal plane including bottommost surfaces of the plurality of raised active regions (6S, 6D). The plurality of raised active regions (6S, 6D) can be formed over the dielectric material portion (within the insulator layer 20), and a bottommost portion of each contiguous metal semiconductor alloy region (8S, 8D) can be formed above the dielectric material portion. Thus, a bottommost surface of each contiguous metal semiconductor alloy region (8S, 8D) can be located above the horizontal plane including bottommost surfaces of the plurality of raised active regions (6S, 6D).

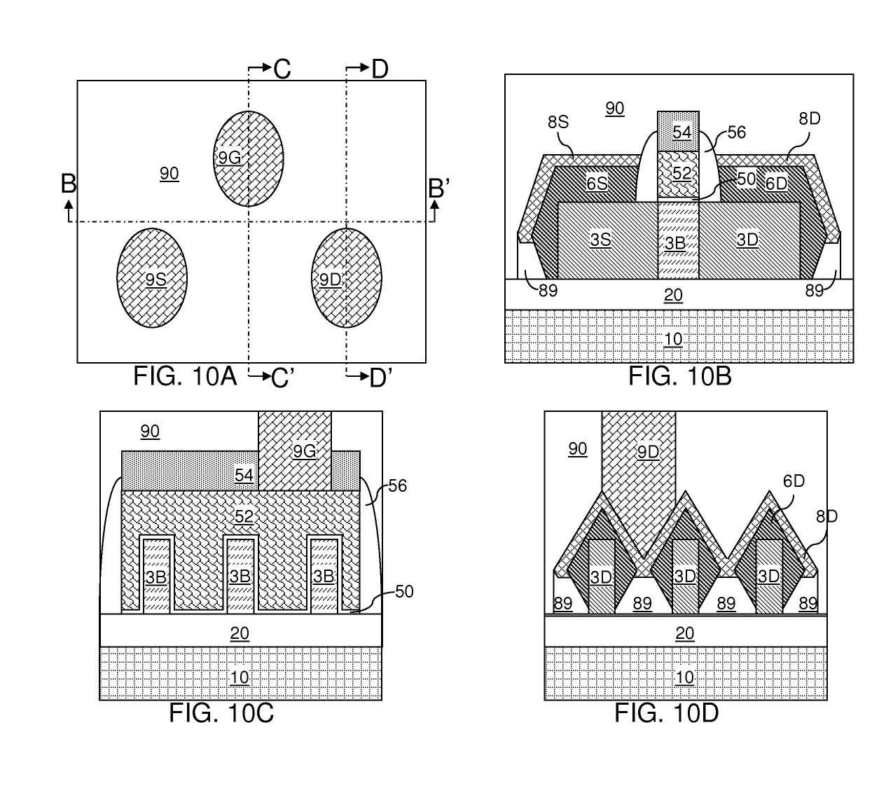

Referring to FIGS. 10A-10D, a third variation of the first exemplary semiconductor structure can be derived from the first variation of the first exemplary semiconductor structure by forming the contiguous metal semiconductor alloy regions (8S, 8D) employing a non-conformal deposition method for deposition of a metallic material or a metal semiconductor alloy material. A dielectric material portion (such as the insulator layer 20) can be located below a horizontal plane including bottommost surfaces of the plurality of raised active regions (6S, 6D). The plurality of raised active regions (6S, 6D) can be formed over the dielectric material portion (within the insulator layer 20), and a bottommost portion of each contiguous metal semiconductor alloy region (8S, 8D) can be formed above the dielectric material portion. Thus, a bottommost surface of each contiguous metal semiconductor alloy region (8S, 8D) can be located above the horizontal plane including bottommost surfaces of the plurality of raised active regions (6S, 6D).

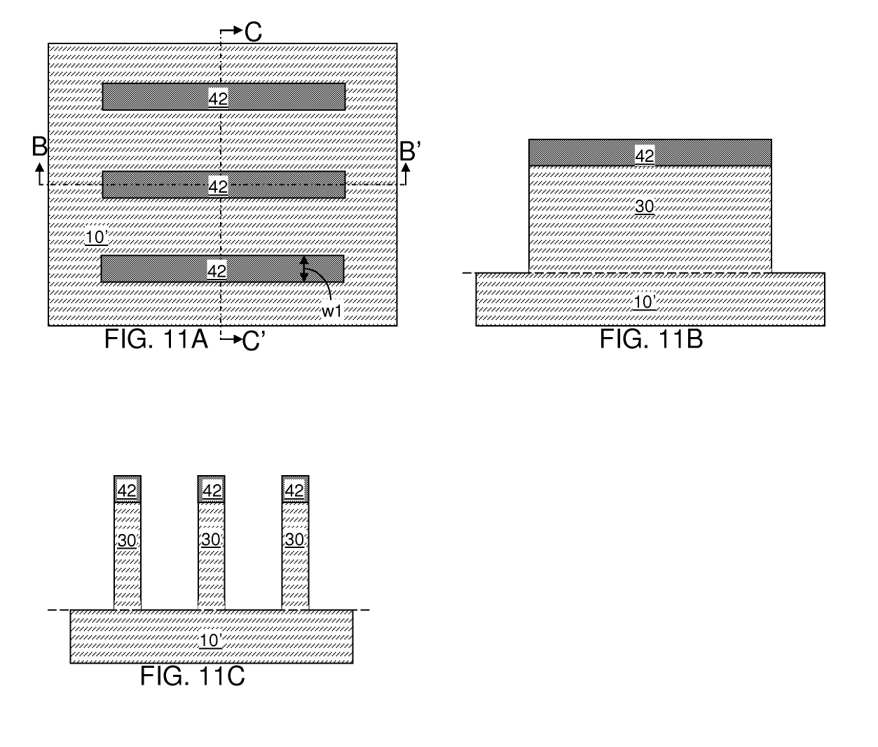

Referring to FIGS. 11A-11C, a second exemplary semiconductor structure according to a second embodiment of the present disclosure can be derived from the first exemplary semiconductor structure by replacing the combination of a handle substrate 10 and an insulator layer 20 with a bulk semiconductor substrate 10′ that is in epitaxial alignment with the semiconductor layer 30L. The processing steps of FIGS. 1A-1C and FIGS. 2A-2C can be performed to form a plurality of semiconductor fins 30. For example, the plurality of semiconductor fins 30 can be formed by an anisotropic etch that employs a plurality of fin-defining mask structures 42 as an etch mask. The plurality of semiconductor fins 30 can have substantially vertical sidewalls.

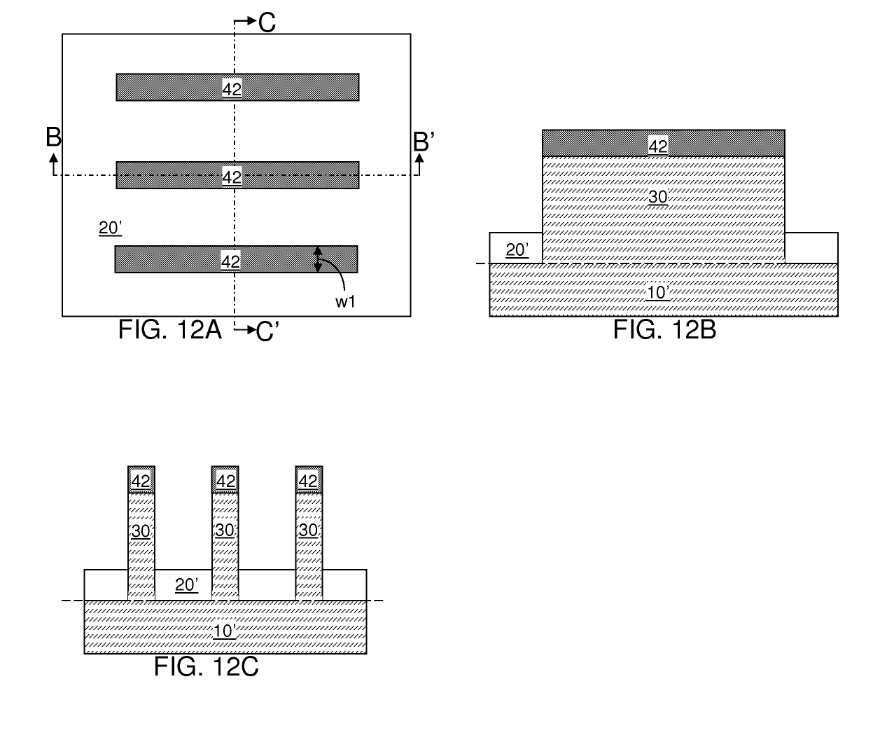

Referring to FIGS. 12A-12C, an insulator layer 20′ can be formed on the top surface of the bulk semiconductor substrate 10′. The insulator layer 20′ can be formed, for example, by spin coating of a dielectric material, or can be formed by deposition of a dielectric material, optional planarization, and recessing of the deposited dielectric material. The insulator layer 20′ can constitute a shallow trench isolation structure.

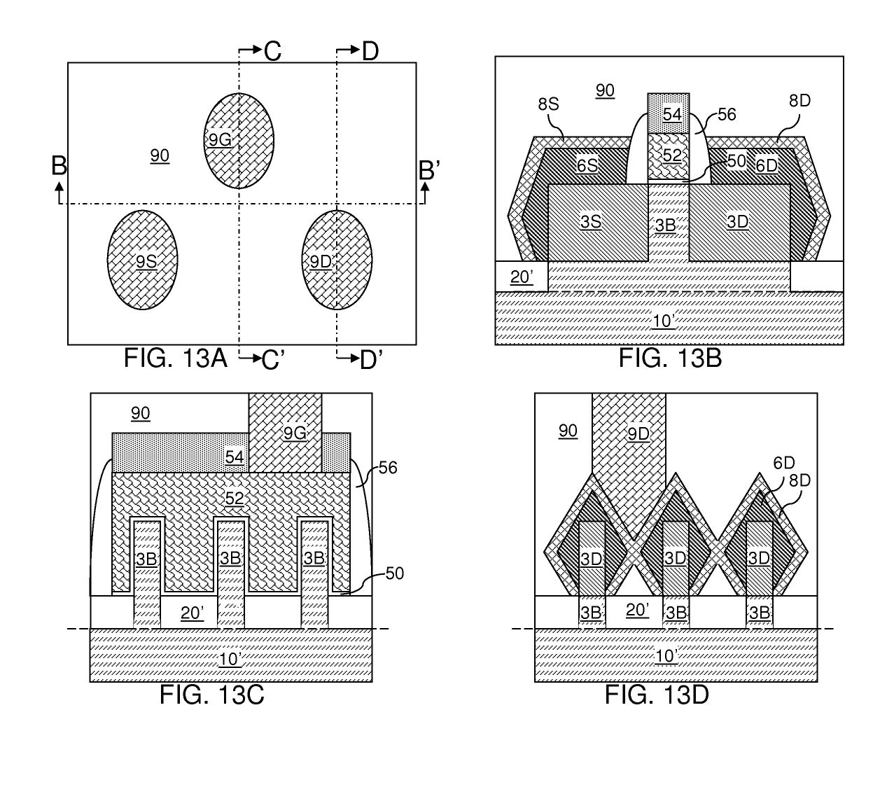

Referring to FIGS. 13A-13D, the processing steps of FIGS. 3A-3C, 4A-4D, 5A-5D, 6A-6D, and 7A-7D can be performed. Alternatively, the processing steps of FIGS. 8A-8D, FIGS. 9A-9D, or FIGS. 10A-10D can be performed instead of the processing steps of FIGS. 7A-7D. A dielectric material portion (such as the insulator layer 20′) can be located below a horizontal plane including bottommost surfaces of the plurality of raised active regions (6S, 6D). The plurality of raised active regions (6S, 6D) can be formed over the dielectric material portion (within the insulator layer 20′), and a bottommost portion of each contiguous metal semiconductor alloy region (8S, 8D) can be formed above the dielectric material portion. The dielectric material portion may be in contact with a bottommost surface of the contiguous metal semiconductor alloy regions (8S, 8D), or may be vertically spaced from the bottommost surface of the contiguous metal semiconductor alloy regions (8S, 8D) as illustrated in FIGS. 9A-9D or FIGS. 10A-10D depending on the deposition method employed to deposit a metallic material or a metal semiconductor alloy material that is employed to form the contiguous metal semiconductor alloy regions (8S, 8D).

The various semiconductor structures of embodiments of the present disclosure increases the contact area between the raised active regions (6S, 6D) and the contiguous metal semiconductor alloy regions (8S, 8D) by providing angled interfaces thereamongst, while enabling use of a lesser number of source-side contact via structures 9S than the number of source regions 3S, and use of a lesser number of drain-side contact via structures 9D than the number of drain regions 3D. Thus, the contact resistance between the raised active regions (6S, 6D) and the contiguous metal semiconductor alloy regions (8S, 8D) is reduced relative to prior art structures employing a merged raised source region or a merged raised drain region, while parasitic capacitance between the gate electrode 52 and the source-side contact via structures 9S and the drain-side contact via structures 9D can be reduced relative to prior art structures employing non-merged raised source regions or non-merged raised drain regions.

While the disclosure has been described in terms of specific embodiments, it is evident in view of the foregoing description that numerous alternatives, modifications and variations will be apparent to those skilled in the art. Each of the embodiments described herein can be implemented individually or in combination with any other embodiment unless expressly stated otherwise or clearly incompatible. Accordingly, the disclosure is intended to encompass all such alternatives, modifications and variations which fall within the scope and spirit of the disclosure and the following claims.

1. A semiconductor structure comprising:
a plurality of semiconductor fins located on a substrate;
a plurality of raised active regions, wherein each of said plurality of raised active regions is located on sidewalls of a corresponding semiconductor fin among said plurality of semiconductor fins, and is laterally spaced from any other of said plurality of raised active regions, and wherein each plurality of raised active regions comprises angled sidewall surfaces that are not parallel or perpendicular to a topmost horizontal surface of said substrate; and
a contiguous metal semiconductor alloy region contacting at least said angled sidewall surfaces of at least two of said raised active regions that are facing each other.

2. The semiconductor structure of claim 1, further comprising:
a gate dielectric straddling said plurality of semiconductor fins; and
a gate electrode overlying said gate dielectric.

3. The semiconductor structure of claim 1, further comprising a contact level dielectric material layer in contact with said contiguous metal semiconductor alloy region.

4. The semiconductor structure of claim 3, further comprising a contact via structure extending through said contact level dielectric material layer and in contact with said contiguous metal semiconductor alloy region.

5. The semiconductor structure of claim 3, further comprising a cavity located underneath said contiguous metal semiconductor alloy region and between a neighboring pair of raised active regions among said plurality of raised active regions.

6. The semiconductor structure of claim 1, wherein an interface between said plurality of raised active regions and said contiguous metal semiconductor alloy region is at an angle that is greater than 0 degree and less than 90 degree with respect to a vertical direction included within said sidewalls of said plurality of semiconductor fins.

7. The semiconductor structure of claim 1, wherein each of said plurality of raised active regions is epitaxially aligned to said corresponding semiconductor fin among said plurality of semiconductor fins.

8. The semiconductor structure of claim 1, wherein said plurality of raised active regions comprises silicon, and said contiguous metal semiconductor alloy region comprises a metal silicide.

9. The semiconductor structure of claim 1, further comprising a dielectric material portion located below a horizontal plane including bottommost surfaces of said plurality of raised active regions, wherein said dielectric material portion is in contact with a bottommost surface of said contiguous metal semiconductor alloy region.

10. The semiconductor structure of claim 1, further comprising a dielectric material portion located below a horizontal plane including bottommost surfaces of said plurality of raised active regions, wherein a bottommost surface of said contiguous metal semiconductor alloy region is located above said horizontal plane.

11.-20. (canceled)

21. A semiconductor structure comprising:
a plurality of semiconductor fins located on a substrate;
a plurality of raised active regions, wherein each of said plurality of raised active regions is located on sidewalls of a corresponding semiconductor fin among said plurality of semiconductor fins, and is laterally spaced from any other of said plurality of raised active regions, and wherein each plurality of raised active regions has faceted sidewall surfaces; and
a contiguous metal semiconductor alloy region contacting at least said faceted sidewall surfaces of at least two of said raised active regions that are facing each other.

22. The semiconductor structure of claim 21, further comprising:
a gate dielectric straddling said plurality of semiconductor fins; and
a gate electrode overlying said gate dielectric.

23. The semiconductor structure of claim 21, further comprising a contact level dielectric material layer in contact with said contiguous metal semiconductor alloy region.

24. The semiconductor structure of claim 23, further comprising a contact via structure extending through said contact level dielectric material layer and in contact with said contiguous metal semiconductor alloy region.

25. The semiconductor structure of claim 23, further comprising a cavity located underneath said contiguous metal semiconductor alloy region and between a neighboring pair of raised active regions among said plurality of raised active regions.

26. The semiconductor structure of claim 21, wherein an interface between said plurality of raised active regions and said contiguous metal semiconductor alloy region is at an angle that is greater than 0 degree and less than 90 degree with respect to a vertical direction included within said sidewalls of said plurality of semiconductor fins.

27. The semiconductor structure of claim 21, wherein each of said plurality of raised active regions is epitaxially aligned to said corresponding semiconductor fin among said plurality of semiconductor fins.

28. The semiconductor structure of claim 21, wherein said plurality of raised active regions comprises silicon, and said contiguous metal semiconductor alloy region comprises a metal silicide.

29. The semiconductor structure of claim 21, further comprising a dielectric material portion located below a horizontal plane including bottommost surfaces of said plurality of raised active regions, wherein said dielectric material portion is in contact with a bottommost surface of said contiguous metal semiconductor alloy region.

30. The semiconductor structure of claim 21, further comprising a dielectric material portion located below a horizontal plane including bottommost surfaces of said plurality of raised active regions, wherein a bottommost surface of said contiguous metal semiconductor alloy region is located above said horizontal plane.
